(19) United States
(12) Patent Application Publication
(10) Pub. No.: US 2012/0298177 A1
(43) Pub. Date: Nov. 29, 2012

(54) CONCENTRATING PHOTOVOLTAIC SYSTEMS WITH OFFSET PHOTOVOLTAIC DEVICES AND/OR ASSOCIATED METHODS

(76) Inventors: Robert A. VANDAL, Syracuse, IN (US); Darrin Neitzke, Marysville, MI (US)

(21) Appl. No.: 13/116,467

(22) Filed: May 26, 2011

(51) Int. Cl. H01L 31/052; H01L 31/18; H01J 40/14; B23P 11/00

(52) U.S. Cl. 136/246; 29/428; 29/407.06; 250/216

(57) ABSTRACT

Certain example embodiments relate to improved concentrating photovoltaic (CPV) systems and/or methods of making the same. Certain example embodiments relate to positing a photovoltaic array at a distance that is offset from a calculated theoretical focus of a reflector. In certain example embodiments, the distance is determined by performing a ray trace against the reflector such a distribution of the rays may be determined. In certain example embodiments, the offset is determined by selecting a range where at least 95% of the rays are included in the range. In certain example embodiments, a CPV system includes a reflector that reflects solar energy to a PV array that is located at a distance that is offset from a theoretical focus distance of the reflector.

### FIELD OF THE INVENTION

Certain example embodiments relate to improved concentrating photovoltaic (CPV) systems, and/or methods of making the same. More particularly, certain example embodiments relate to techniques for increasing the efficiency of CPV systems by moving the solar cells within the systems to take advantage of variances in mirror construction.

### BACKGROUND AND SUMMARY OF EXAMPLE EMBODIMENTS OF THE INVENTION

The energy needs of society are constantly growing. Techniques to meet this growing energy demand are continually sought after. One area of focus has been in the area of solar power. Solar power technology can take various forms. For instance, various types of photovoltaic devices are known in the art (e.g., see U.S. Patent Document Nos. 2004/02618411, 2006/0180200, 2008/0308147; U.S. Pat. Nos. 6,784,361, 6,288,325, 6,613,603, and 6,123,824, the disclosures of which are each hereby incorporated by reference).

One area of solar power technology that is of potential interest is the usage of optics to further concentrate the energy from sunlight into a relatively small area. This can be done in the form of concentrating solar power (CSP) devices or concentrating photovoltaic (CPV) devices.

In CSP applications, the energy is typically focused a point or a line. For example, energy from the sun may be optically reflected energy and focused on a linear tube or a localized body of a given focus size. In either case, the receiver at the focus typically carries a heat transfer fluid, which is heated by the focused solar energy as it is pumped through the receiver. In such cases, even though the energy is designed to focus at a line or a point, in practice, the focused energy has some distribution. This may be related to variations or small errors in the original manufacturing of the optical reflector and its supporting components. In CSP system, this lack of “perfect” focus is of little importance because a receiver can be designed to be large enough to capture the vast majority of the distributed energy. The desired size of the receiver is usually limited as a result of heat loss considerations. However, in practical applications, a match between the energy distribution and the receiver size can usually be obtained. Specifically, the nature of the fluid system is typically such that the fluid itself will serve to homogenize the temperature distribution over the receiver. Thus, even though the reflected energy is not focused on one point or line, it is still collected and there is little to no waste.

Unlike CSP systems, CPV systems typically use a distributed energy model (e.g., not focused at one point). FIG. 1 shows a traditional CPV system 100 that includes a parabolic trough 104 that focuses solar radiation from sun 102 onto a photovoltaic (PV) array 106. In a CPV system, the PV array 106 replaces the heat transfer system that is designed to heat fluid in the CSP system. Furthermore, in CPV systems, unlike the thermal receiver in CSP applications, the heat that is part of the reflected energy is generally undesirable for the solar cells in the CPV system. This may be especially true for focused heat, which can create “hot spots” that can sometimes damage the PV array and/or reduce its efficiency because of the excess heat. On the other side of the coin, it is also desirable for the entire cell surface (or a significant portion thereof) to be illuminated by the focused energy, inasmuch as “dark cells” will produce a reduced amount of power output (if any) and also can sometimes degrade the performance of other cells that are placed in series with the non-producing cells.

Conventionally, creation of a distributed focus for CPV applications is done by modifying the designed shape of the reflector surface to a new curvature such that a parabola is no longer defined. Instead, a new shape, or series of shape segments, is constructed that comprise the reflector surface. One technique for accomplishing this is by creating segments and combining the segments together in a design. Another method may be to define more complicated shapes mathematically with higher order polynomial equations. Thus, conventionally, a shape may be defined which, if manufactured accurately, will yield the desired energy distribution at the designed focus distance.

While this method may work in theory, construction of mirrors and optical surfaces can be very complex and often results in large or small imperfections. For example, when the Hubble Space Telescope initially launched, the primary mirror contained a flaw in which the mirror was off by about 10 nanometers. In order to keep CPV an efficient solution for power generation, creation of a mirror that very closely matches the design may be cost prohibitive or otherwise technically infeasible to produce. Furthermore, imperfect reflections may result from the stack up of tolerances of the associated support components. Accordingly, a reflector may never achieve a perfectly ideal shape and/or focus despite best efforts to the contrary.

As discussed above, a parabola designed with a point or line focus, due to manufacturing variations, yields a distributed energy field at the target around the point or line of focus. For CPV reflectors, the same phenomenon may still exist, however it may now be a series of overlapping distributions that depend in part on the method that was chosen to design the reflector shape, e.g., when intentionally designed in accordance with a higher order polynomial shape or in a system with multiple mirrors, or simply as an unintended result of minor manufacturing imperfections. In the central areas of the receiver PV array, the fact that this is a group of distributions, rather than a result of the specific design, may be of little consequence as the overlaps tend to wash together. However, near the edge of the receiver array, these distributions may result in significant spillage of focused energy beyond the useable edges of the PV array.

While these “unusable” edges may be corrected through better manufacturing. As noted above, the complexity associated with manufacturing reflectors in such a precise and cost effective manner is currently not always feasible on a large commercial scale. Accordingly, current designs, by their very nature, with nominal focus points at or near the edges of the receiver, will result in a spillage of energy. This, in turn, creates efficiency losses and higher costs.

The statistical deviations for the focus points due to manufacturing variations will typically be in all possible directions from the focus point, with an average typically at or near the nominal value for a good manufacturing process. Accordingly, for a focus that is nominally at an edge of the receiver array, approximately half of the energy designated to hit that focus will be within the surface of the receiver. Conversely, the other half will spill beyond the edge of the receiver. The conventional approach to addressing this flaw is to “cheat” in a particular direction the portions of the reflector that focus near edges (e.g., inward).

Accordingly, it will be appreciated that new and improved techniques for CPV applications are continually sought after. It will also be appreciated that there exists a need in the art for techniques that increase the illumination efficiency of CPV application and/or reducing the prevalence of hot spots and/or dark spots.

In certain example embodiments, a theoretical focal location is calculated for a designed reflector. An offset between the theoretical focal location and energy convergence is determined. The position of a PV array is set or adjusted based on the determined offset value.

In certain example embodiments, a method of making or assembling a CPV system is provided. A reflector is disposed that has a theoretical focus at a first distance from a vertex of the reflector as part of the CPV system. A PV array is positioned at a second distance that is an offset distance from the first distance, the first distance based on a calculated actual energy distribution criteria. The reflector is configured to reflect solar energy from the reflector towards the photovoltaic array.

In certain example embodiments, a method of improving the efficiency of a photovoltaic (PV) array used in a CPV system is provided. The PV array is adjusted by an offset distance from an ideal theoretical distributed focus or point focus of a reflector that is configured to reflect solar energy onto to the PV array.

In certain example embodiments a method of determining the arrangement of a solar cell in a concentrating photovoltaic (CPV) system is provided. A plurality of ray traces is performed against a reflector that is configured to be an element of the CPV system. A distribution is calculated based on the plurality of ray traces intercepting a plane that is a predetermined distance from a vertex of the produced reflector. A range is determined where at least a predetermined amount of the distribution of the plurality of ray traces falls within the range. An improved focus distance is calculated from the vertex of the produced reflector based on the distribution

In certain example embodiments the reflector is an already formed reflector that includes at least one deviation from the designed version of the reflector.

In certain example embodiments, the ray traces are performed against a plurality of reflectors and an average distribution is used to determine the range and/or improved focus distance.

In certain example embodiments a concentrating photovoltaic (CPV) system is provided. The CPV system includes a reflector that is configured to reflect solar energy. The reflector is also designed to have a theoretical focus distance from the vertex of the reflector. A PV array is located at a distance that is offset from the theoretical focus distance by a calculated amount. In certain example embodiments, the distance is further away from the vertex than the theoretical focus distance. In certain example embodiments, the distance is closer to the vertex than the theoretical focus distance. The distance may be determined by a distribution of ray traces against the reflector.

The features, aspects, advantages, and example embodiments described herein may be combined in any suitable combination or sub-combination to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a cross-sectional view a conventional concentrating photovoltaic system;

FIG. 2 is a cross-sectional view of a CPV system with an overlay of example theoretical and actual energy distribution of a distributed focus reflector according to certain example embodiments;

FIG. 3 is a cross-sectional view of a concentrating power system showing actual energy distribution of a point focused reflector according to certain example embodiments;

FIGS. 4A-4C are cross-sectional views of CPV system illustrating adjusting the location of a PV array according to certain example embodiments;

FIGS. 5-6 are graphs showing example energy distribution from produced reflectors; and

FIG. 7 is a flow chart show an example process for implementing an example CPV system according to certain example embodiments.

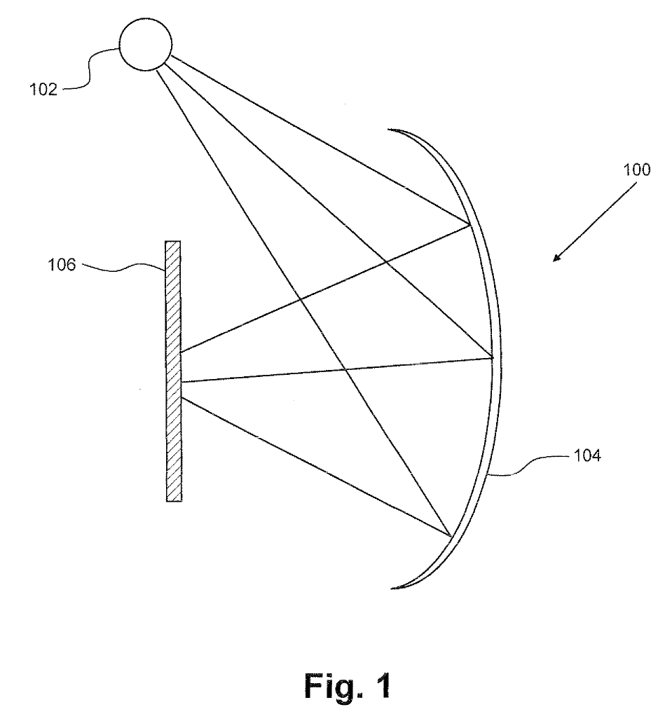

### DETAILED DESCRIPTION OF EXAMPLE EMBODIMENTS OF THE INVENTION

The following description is provided in relation to several example embodiments which may share common characteristics, features, etc. It is to be understood that one or more features of any one embodiment may be combinable with one or more features of other embodiments. In addition, single features or a combination of features may constitute an additional embodiment(s), e.g., in any suitable combination or sub-combination.

Certain example embodiments herein relate to CPV systems and/or method of creating and/or installing the same.

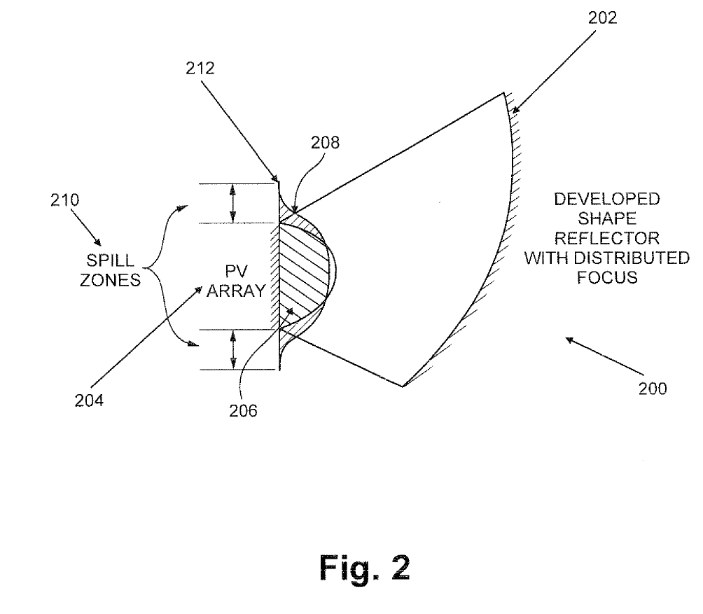

Referring now more particularly to the accompanying drawings in which like reference numerals indicate like parts throughout the several views, FIG. 2 is a cross-sectional view of a CPV system with an overlay of example theoretical and actual energy distribution. Here, CPV system 200 includes a shaped reflector that is designed with a distributed focus at area 212. Plane 212 is where the PV array 204 is located to receive the concentrated solar energy reflected by reflector 202. During the design of reflector 202, a theoretical energy distribution 206 may have been calculated. This may be done in order to determine an optimum position for the PV array 204 in relation to the reflector 202. However, as noted above, the manufacturing process and the subsequent assembly of the CPV system 200 most likely will introduce errors in to the system. Accordingly, in contrast to the theoretical energy distribution 206, the actual energy distribution from the reflector in the shaded area 208 is not quite as bunched in the middle as the theoretical energy distribution 206. Accordingly, reflected energy may fall outside of the area covered by the PV array 204 and into the spill zones 210. In other words, the energy hitting/crossing the plane 212 in the spill zones 210 is lost and not converted by the PV array. It will be appreciated that this results in inefficiency in the CPV system and may be undesirable. It also will be appreciated that different implementations may include one or more spill zones of the same or different shapes depending on, for example, the position of the reflector relative to the PV array; the number, types, severities, and/or locations of imperfections existing in the reflector; etc.

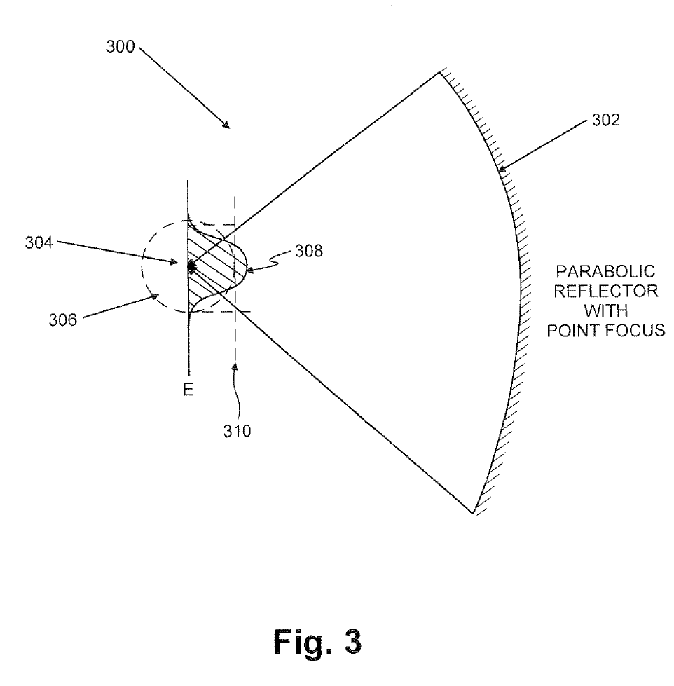

FIG. 3 is another cross-sectional view of a concentrating power system, showing actual energy distribution of a point focused reflector according to certain example embodiments. Point focused reflectors are typically used in conjunction with CSP systems. However, it may be desirable to adapt such reflectors to CPV systems or at least more CPV-like systems. It also may sometimes be desirable to adapt CSP systems such that a more uniform heating is achievable across a distance (e.g., diameter) of the tube holding the heating liquid, etc., and/or reduce spillage of the type described above in connection with FIG. 2. In FIG. 3, system 300 includes a parabolic reflector 302 that focuses to point focus 304. In a typical CSP system, a thermal receiver tube 306 is placed around the point focus. As discussed above, the thermal distribution of the liquid in the tube is designed to allow substantially all of the solar energy reflected from reflector 302 to be captured in tube 306. The actual energy distribution as a result of the reflection is shown in shaded area 308. With the data of the actual energy distribution, an optimal plane 310 (in a de-focused position) for the placement of a CPV array and/or the repositioning of the tube may be determined. Accordingly, based on this information, a point focused reflector 302 may be adapted to work efficiently with a CPV system, and/or to possibly improve the efficiency of the CSP system.

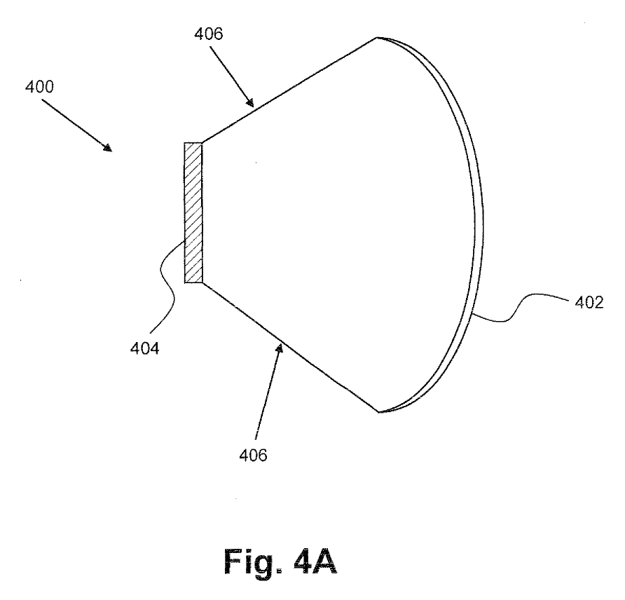

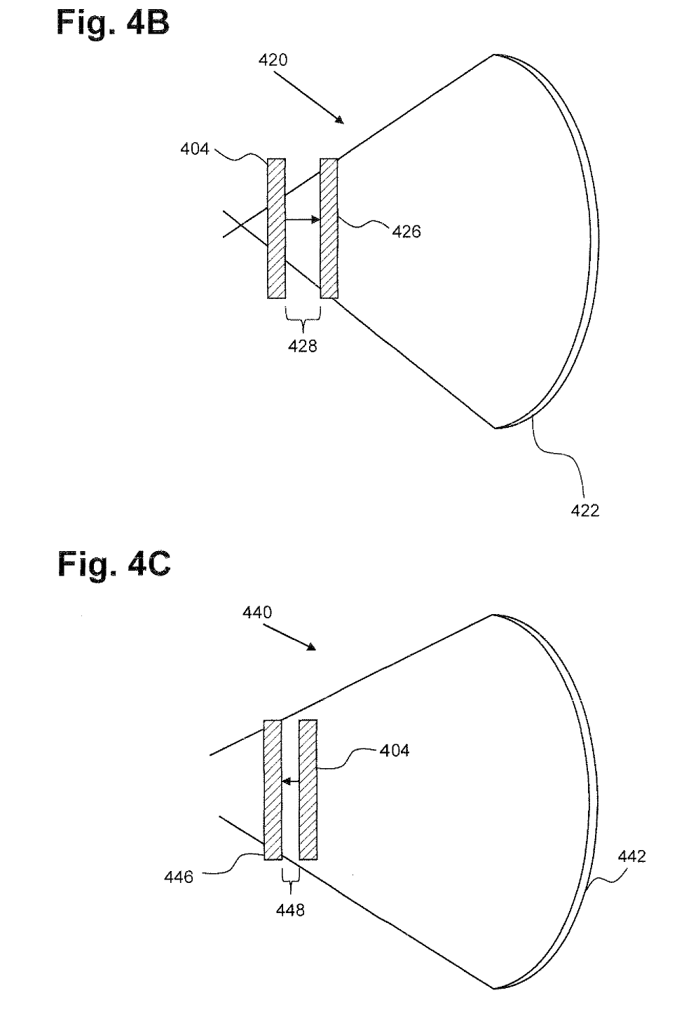

FIGS. 4A-4C are cross-sectional views of a CPV system illustrating adjusting the location of a PV array according to certain example embodiments. As discussed above, although a reflector may be designed to be perfect, imperfections as a result of the manufacturing process and/or assembly process may result in an imperfect mirror when produced and/or assembled and thus having an imperfect energy distribution. In FIG. 4A, an ideal mirror 402 is shown in a CPV system 400. Solar energy 406 reflected from reflector 402 is perfectly aligned with the designed placement of a PV array 404.

However, in practice, the design for energy distribution does always not match the actual energy distribution. FIG. 4B shows a cross-sectional view of a CPV system in which the perfectly designed reflector 402 is flawed such that the focal point is closer to the reflector 422 than the designed version. Accordingly, if the PV array 404 is left at the previously designed-for position, some of the cells in the PV array 404 may be overly heated or dark and, thus, less efficient than they otherwise would be. Accordingly, for CPV system 420, a PV array 426 is moved by a calculated offset amount 428 towards the reflector panel. Thus, PV array 426 may be more properly positioned with respect to the actual energy distribution of the reflector 422. In certain example embodiments, this may result in an increased efficiency of the CPV system.

FIG. 4C shows an example CPV system that has the opposite problem of the closer focal point described above. Here, the actual energy distribution from reflector 442 results in a portion of the solar energy from reflector 442 completely missing the PV array 404. As will be appreciated, one result of this energy missing the PV array 404 is a decrease in efficiency of the CPV system 440. Accordingly, an offset 448 may be calculated. The result of this offset may be a determination to move a PV array 446 back or further away from the reflector 442 such that PV array 446 substantially catches all of the solar energy (or at least a greater percentage thereof) from the reflector 442.

In certain example embodiments, the determination of the actual distribution of solar energy being reflected from a constructed reflector may be determined by ray tracing the reflector. Alternatively, or in addition, other methods may be used to determine the actual energy distribution from a reflector including, for example: observing the actual flux line of energy on a target screen with the reflector in artificial or natural light; deflectometric or photogrammetric analysis using analysis software for analyzing surfaces and/or reflectors, etc. For example, the QDec deflectometry system provided by CSP Services of Germany or VSHOT laser trace analysis provided by NREL in Colorado may be used in assessing the energy distribution of a reflector (or a group of reflectors).

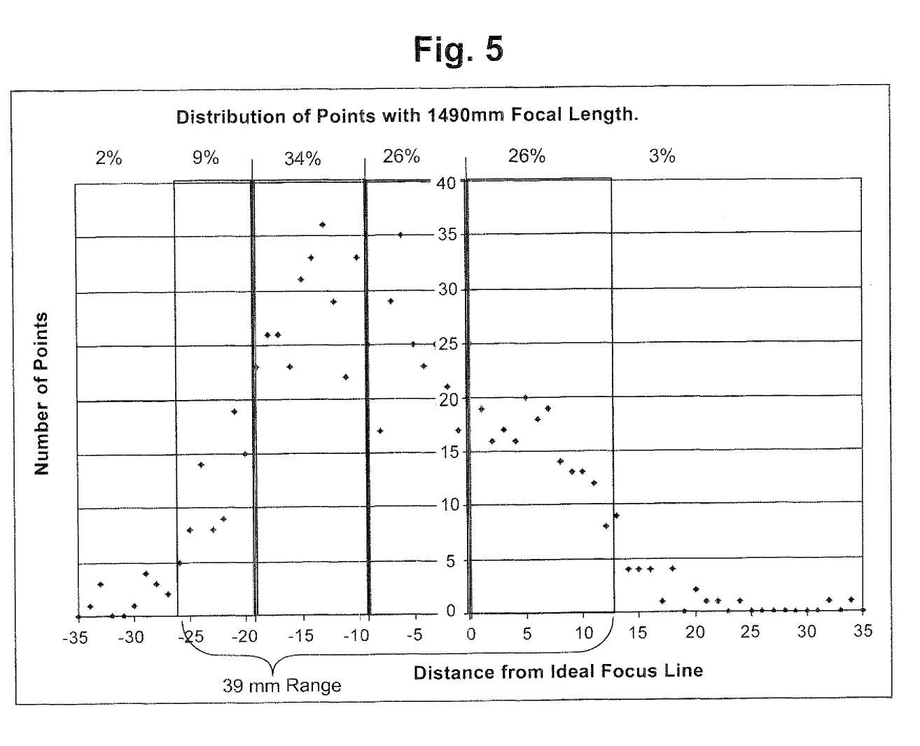

FIG. 5 shows a graph of an example energy distribution as the result of ray tracing an exemplary designed reflector. It is noted that the FIG. 5 data has been gathered in connection with a CSP parabolic trough system known in the industry as RP-2. In this particular example, the designed reflector has a focal length of 1490 mm from the vertex of the reflector. Such a reflector may be typical of a conventional CSP application. Here, the data shown represents samples from 30 different reflectors produced according to this design. Approximately 1000 points of evenly distributed ray traces were done over the surface of the produced reflectors. The x-axis represents a plus or minus distance from a plane at the 1490 focal length (with 0 being 1490 mm from the reflector). In certain example embodiments, a screen may be placed at 1490 mm from the panel to facilitate the capturing of the ray traces. The y-axis represents a number of points hitting at a particular distance. In certain example embodiments, a range may be selected such that at least 90% of the ray traced data hits within the range, more preferably at least 95%, and even more preferably at least 97%. FIG. 5 shows that about 95% of the ray traces hit within a 39 mm range between about −26 mm from the focal point to about 13 mm from the focal point. In certain example embodiments, this may result in an increase in captured solar energy. In certain example embodiments, when statistical methods are implemented, the amount of energy that does not impinge upon the PV array after its placement has been adjusted preferably lies outside of 2 standard deviations from a central area of the distribution, more preferably outside of 3 standard deviations, and sometimes even further.

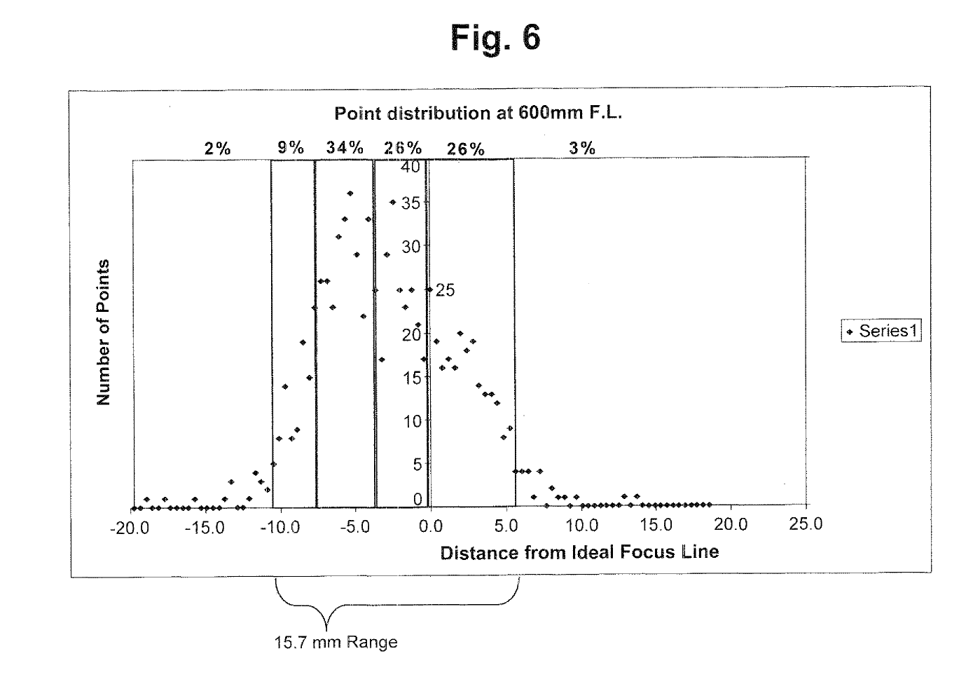

FIG. 6 shows another graph with an example energy distribution from the same above sampled 30 reflectors where the reflectors were scaled to give a distribution based on the same reflector manufacturing accuracy but with a designed focal length of about 600 mm. As can be seen the relative distribution of the points from the ray tracing is similar to the above FIG. 5. However, in this graph, the range where about 95% of the traces are located is within a 15.7 mm range. Accordingly, the range may be selected such that at least 90% of the ray traced points are within the selected range, more preferably at least 95%, and even more preferably at least 97%. Thus, FIG. 6 shows a distance from the vertex that is smaller with an increased concentration of energy while maintaining the same or a similar distribution of reflected energy.

Certain example embodiments advantageously result in a more even distribution of heat across a PV array, thereby reducing the likelihood of the formation of hot spots and/or dark cells that may degrade performance of the overall system.

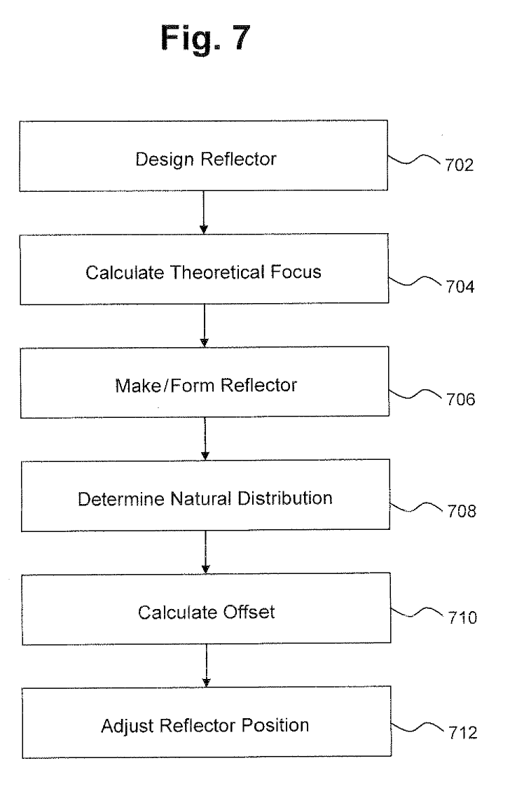

FIG. 7 is a flow chart showing an example process for implementing an exemplary CPV system according to certain example embodiments. In step 702 a reflector is initially designed. As part of the design process, a theoretical focal point for the reflector (or multiple focal points) may be calculated in step 702. In certain embodiments, a theoretical energy distribution may be calculated.

After designing the reflector, it may be assembled or formed in step 706. For example, certain example embodiments may form reflectors as described in U.S. application Ser. No. 12/923,836, the entire contents of which are hereby incorporated by reference. After forming the reflector in step 706, the natural energy distribution of the constructed reflector may be determined in step 708. For example, the above described ray tracing method may be used to determine an approximation of energy distribution. In certain instances, the distribution may a substantially normal or Gaussian distribution around the theoretical focus of the formed reflector, although other distributions are possible. In certain example embodiments, it may be assumed that the distribution is substantially normal or Gaussian in nature, whereas other example embodiments may not make this assumption and/or may involve actual measurements.

Based on this determination, an offset position may be derived. In certain example embodiments, the offset position may be offset from the ideal focal point (e.g., as shown in FIG. 3) or an ideal distributed focus (e.g., FIG. 2). Alternatively, or in addition, the calculated position may be calculated in relation to the vertex (or some other location) of the reflector panel.

Furthermore, the determination of an offset position may be based on sampled data from multiple reflectors (e.g., 30 as discussed in connection with FIG. 5, or some other number such as, for example, the number of reflectors in the assembly or a portion of the assembly; the number of reflectors produced, shipped, or installed in a batch, in a predefined area, or in a time window, or some percentage thereof; etc.). Alternatively, the offset position may only be based on sampled information from the reflector that is to be adjusted. In any event, once the offset position or a “best fit” position is determined, the PV array may be placed.

As noted above, the reflectors for CSP applications may be modified for use in CPV applications. In certain example embodiments, such modifications may include scaling the mirrors produced for CSP application for CPV applications (e.g., as shown in with respect to FIGS. 5 and 6). Accordingly, certain example embodiments may measure the energy distribution from mirrors designed for CSP applications (e.g., FIG. 5) and then scale the energy distribution, focal length, etc., to estimate the actual energy distribution of mirrors for CPV applications (e.g., FIG. 6).

Accordingly, in certain example embodiments, some of the steps in FIG. 7 may be done with respect to a reflector with a longer or shorter focus than the reflector actually installed in a CPV application. For example, steps 704 and/or 708 may be done for a first mirror type (e.g., FIG. 5—1490 mm) and then the offset may be calculated for another mirror type (e.g., FIG. 6—600 mm). Thus, the determination of a particular offset for a mirror may be scaled based on how much the focal length is adjusted between the first mirror type and the second mirror type.

The inventors of the instant application discovered that information concerning the same manufacturing process that is used to make panels of similar size but shorter (or longer) focal lengths may allow the data (e.g., the distribution of reflected energy) from a first type of reflector to be scaled to a second type of reflector. This may allow the prediction of the energy distribution at the new focal line without having to perform new energy distribution tests.

As will be appreciated from the brief description provided above, direct information about the accuracy and manufacturing variation of panels of a given family of size and/or focal length may be obtained. Knowing that the same manufacturing process will be used to make further panels of a similar size but of a shorter focal length for another application (e.g., CPV vs. CSP, or vice versa) or another implementation (e.g., CPV vs. CPV, or CSP vs. CSP), it is possible to use that data and scale it to the rough desired focal length for the end-customer and predict for that focal length a new distribution at the focal line (e.g., as done in connection with FIGS. 5 and 6). This may help reduce the need to make each specific configuration before having an idea of the natural distribution expected. Knowing the distribution at the focus line then allows easy prediction of where in space the distribution will be best suited to the particular CPV array.

It will be appreciated that one or more of the above steps may be carried out by one or more entities. Further, one or more steps may constitute separate embodiments in relation to building and/or assembling PV systems. For example a constructed reflector may be adjusted based on the actual energy distribution (as opposed to the theoretical). The reflector manufacturer may, for example, be the same or different party as the PV array manufacturer. These manufacturing parties may be the same or different from installers/integrators, solar field operators, etc. Thus, the example steps described above may be performed by these parties, as appropriate to a particular business process or model.

Although certain example embodiments have been described in relation to moving a PV array closer to or father away from an ideal position, it will be appreciated that the offset may be a “side to side” or “left or right” adjustment. It also will be appreciated that the new or offset location need not necessarily be parallel or even substantially parallel to or in line with the ideal or theoretical location. For instance, the offset may relate to an angle relative to an ideal or theoretical position, and/or a combination of up-or-back and left-and-right movement. In certain example embodiments, it may be desirable to adjust the curvature of a PV array.

Although certain example embodiments relate to offsetting the positioning of PV arrays, another aspect of certain example embodiments relates to adjusting the size of the PV arrays (e.g., to make them larger or smaller). Similarly, certain example embodiments may relate to detecting where hot spots or dark cells occur and changing the manner or series in which the solar cells are connected.

It will be appreciated that the term “focus” does not always refer to a particular point but instead may sometimes refer to an area, e.g., at which energy is directed, where a PV array is focused, where an energy distribution occurs, etc.

Although certain example embodiments have been described in relation to CPV system, it will be appreciated that the techniques described herein may be used in connection with CSP systems. It also will be appreciated that the example techniques described herein may be used to convert CSP systems to CPV systems, and/or to improve the efficiency of already in place CPV systems.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers there between.

While the invention has been described in connection with what is presently considered to be the most practical and preferred embodiment(s), it is to be understood that the invention is not to be limited to the disclosed embodiment, but on the contrary, is intended to cover various modifications and equivalent arrangements included within the spirit and scope of the claims.

What is claimed is:

1. A method of making or assembling a concentrating photovoltaic (CPV) system, the method comprising:
disposing a reflector that has a theoretical focus at a first distance from a vertex of the reflector as part of the CPV system; and
positioning a photovoltaic array at a second distance that is an offset distance from the first distance based on a calculated actual energy distribution criteria,
wherein the reflector is configured to reflect solar energy from the reflector towards the photovoltaic array.

2. The method of claim 1, further comprising calculating the offset by performing a plurality of ray traces on the reflector.

3. The method of claim 2, wherein the plurality of ray traces form a substantially Gaussian distribution of reflected energy onto the installed photovoltaic array and at least 95% of the ray traces falling within an area occupied by the installed photovoltaic array.

4. The method of claim 1, wherein the theoretical focus is at a theoretical focus point or a theoretical distributed focus.

5. The method of claim 1, wherein the second distance is farther away from the vertex of the reflector than the first distance.

6. The method of claim 1, wherein the second distance is closer to the vertex of the reflector than the first distance.

7. The method of claim 1, further comprising determining the theoretical ideal focus for the reflector.

8. The method of claim 7, further comprising making the reflector.

9. A method of improving the efficiency of a photovoltaic (PV) array used in a concentrating photovoltaic system, the method comprising:
adjusting the PV array by an offset distance from an ideal theoretical distributed focus or point focus of a reflector that is configured to reflect solar energy onto to the PV array.

10. The method of claim 9, wherein the offset distance is a negative distance with respect to the ideal theoretical focus or point focus.

11. The method of claim 9, wherein the offset distance is a positive distance with respect to the ideal theoretical focus of point focus.

12. The method of claim 9, wherein adjusting the PV array by the offset distance results in a higher percentage of reflected solar energy hitting the PV array as compared to an arrangement in which the PV array is disposed at the ideal theoretical distributed focus or point focus of the reflector.

13. The method of claim 9, further comprising determining the offset distance by performing a ray tracing operation on the reflector.

14. A method of determining the arrangement of a solar cell in a concentrating photovoltaic (CPV) system, the method comprising:
performing a plurality of ray traces against a produced reflector that is configured to be an element of the CPV system;
calculating a distribution of the plurality of ray traces against a plane that is a predetermined distance from a vertex of the produced reflector;
determining a range where at least a predetermined amount of the distribution of the plurality of ray traces falls within the range; and
calculating an improved focus distance from the vertex of the produced reflector based on the distribution.

15. The method of claim 14, wherein the predetermined amount is at least 95% of the plurality of ray traces.

16. The method of claim 14, further comprising disposing the solar cell in a CPV system based on the improved focus distance.

17. A concentrating photovoltaic system, the system comprising:
a reflector that is configured to reflect solar energy, the reflector designed to have a theoretical focus distance from the vertex of the reflector; and
a PV array that is located at a distance that is offset from the theoretical focus distance by a calculated amount.

18. The system of claim 17, wherein the distance is further away from the vertex than the theoretical focus distance.

19. The system of claim 17, wherein the distance is closer to the vertex than the theoretical focus distance.

20. The system of claim 17, wherein the distance of the PV array is determined by a ray traced distribution of a plurality of ray traces against the reflector.
